(19) United States
(12) Patent Application Publication
(10) Pub. No.: US 2023/0014749 A1
(43) Pub. Date: Jan. 19, 2023

(54) METAL DETECTOR HAVING TRANSMITTER WITH ACTIVE MAGNETIC COMPENSATION

(71) Applicant: NOKTA MUHENDISLIK A.S., Istanbul (TR)

(72) Inventors: Mehmet ONLEK, Istanbul (TR); Basri Kutlu YAVAS, Istanbul (TR); Sadik TAHTA, Istanbul (TR)

(73) Assignee: NOKTA MUHENDISLIK A.S., Istanbul (TR)

(21) Appl. No.: 17/782,671

(22) PCT Filed: Dec. 5, 2019
(86) PCT No.: PCT/TR2019/051033

§ 371 Date: Jun. 6, 2022

(51) Int. Cl. G01R 33/00; G01R 33/09

(52) U.S. Cl. CPC G01R 33/0029; G01R 33/091

(57) ABSTRACT

A metal detector includes at least one sensor that enables to detect the magnetic field created by the transmitter, an error detection system that enables to determine the distortion by comparing the detected magnetic field to the ideal function, and a corrective system which enables to eliminate the distortion by the additional magnetic field that is created according to the detected distortion and/or by the current or voltage applied to the transmitter.

### CROSS REFERENCE TO THE RELATED APPLICATIONS

This application is the national phase entry of International Application No. PCT/TR2019/051033, filed on Dec. 5, 2019, the entire contents of which are incorporated herein by reference.

### TECHNICAL FIELD

The present invention is related to a metal detector which measures the magnetic field created by its transmitter, by means of magnetic sensor or a field measuring coil to determine distortions in the created magnetic field and to eliminate distortions within the magnetic field via compensation by means of generating an additional magnetic field by a second transmitter or adding electrical signal on the present transmitter; in order to create a magnetic field which is closest to the ideal for detecting, discriminating and analyzing a metal target.

### BACKGROUND

The basic operating principle of the metal detectors; may be explained in general such that creating eddy currents in a conductive target within the magnetic field created by means of the magnetic field transmitter constituted of multi-turn coil and measuring the counter magnetic field resulting from these flows by means of the detector receiver. It is possible to refer to the magnetic field created by the detector as the primary field, and the field received from the target as the secondary field. This process is realized by means of either analyzing the components of measured frequency and phase of the secondary magnetic field by creating a magnetic field with continuous wave (CW) or by means of analyzing the reaction occurred during intervals in which there is no induction within time domain by creating an intermittent pulse induction (PI). There are advantages and disadvantages of both techniques in respect to each other, however both methods are based on same physical cause and effect relationship and the signal noise ratio (SNR) of both of them has impact on the performance and thus the success of the detector. As much as the analysis ability the receiver of a metal detector and the units which follow the receiver, the magnetic field created by the receiver which is closer to the ideal is important in detecting and discriminating the target. A part of the noise and distortion occurs in the transmitter and is transmitted to the target. Said noise; either due to electrical signals of the transmitter or occurred during the transformation of the electrical signal into magnetic field, causes distortion in the currents created on the target and thus influences the reaction of the target unfavourably. This condition; causes disturbances in analyses to be made in the receiver which cannot be corrected entirely. This difficulty in analysis; is valid for both the target and the environment and the objects (ground, rocks, salt water) which are required to be distinguished from the target. The searched target and the influences of the environmental structure that embodies this target; cause the noise and distortions within the magnetic field of the transmitter to be more complex; due to both electrical conductivity features and ferromagnetic features. In case a detector which is either designed for industrial purposes or designed for searching metal target within the field can be able to detect the small targets as far as possible and correctly, it is an important characteristic for the eligibility of this device. The preciseness and the quality of the field created on the target is beneficial for detecting the small target from a distance in the detectors that operate particularly in time domain.

There are various patents and literature which deal with the circuits of the transmitter of the metal detectors generally consisting of a coil which enables voltage and current signals to the latter part, the physical and electrical structure of the coil, are beneficial for improving the quality of the magnetic field that is created by means of thereof. Among these, some of them are related to the coil geometry, its physical and structural details, these subjects are out of the scope of this invention. Because the subject of the patent takes advantage of the real time measurement of the magnetic field and aims for enabling electrical and/or magnetic correction, the solutions created by means of only the circuit elements of by the help of the circuit parameters (current, voltage) are beyond the comparison scope of this patent.

The magnetic field created by a coil is proportional to the current which is flowing through this coil for an ideal transmitter coil. The parasitic effects of a real coil create noise and distortion those distinguish the coil from an ideal coil and are considerable for the metal detector. These effects can be in a manner such that the created magnetic field is not proportional with the current and is not independent from time. The sources of these distorting effects are; the internal resistance of the coil wire, the capacitive coupling between the coil windings, the inductive, capacitive and resistive parasitic currents on the cable which carries signal to the coil and the parasitic effects which can be created by the switching elements. These effects are reflected to the created magnetic field as a disturbance however it is not easy to measure the final magnetic field disturbance that is created due to a part of these effects (such as the capacitive effects between the coils).

In the patent document of Allan Westersten No U.S. Pat. No. 7,656,153B2 titled as “Metal detector with improved receiver coil”, a method is proposed for eliminating these capacitive effects which are also valid for the receiver coil. This method brings a novelty in the compensation characteristic of the capacitive effects in the receive coil by means of a double wound receiver coil. This method cannot be realized on the transmitter by means of the “Bifilar coil” wounds, thus Westersten offers a solution for a different problem.

Using a feedback loop in the detector is disclosed in the patent document No U.S. Pat. No. 7,924,012B2 titled as “Metal detector having constant reactive transmit voltage applied to a transmit coil” however the feedback source of this feedback loop is maintained by the electrical circuits, said patent is not related to a feedback received directly from the magnetic field. The subject of the patent No U.S. Pat. No. 9,250,348 B2 titled as “Transmit signal of a metal detector controlled by feedback loops” which has a very similar title for this subject in terms of using a feedback loop for the transmitter is that it uses feedback in the method in which it obtains the basic transmitter wave form. In said study there is no subject as correcting the magnetic field in a conceptual or methodological manner. The feedback loop subject to the patent is a feedback based on measuring the current which is shared in many similar patents of Candy.

In case the magnetic field that is created within the transmit coil, is not proportional to the current that passes through the conductor independent of time due to these parasitic effects, this becomes particularly important when there are fast signal transitions, due to particularly capacitive and inductive effects. These effects result in the partial flow of the current not contributing to creating magnetic field, losses and disturbances in the network circuit which consists of the capacitive and resistive complex elements within the coil.

The patent document of Bruce Halcro Candy No AU2009262370 B2 titled as “Constant current metal detector with driven transmit coil” basically comprises various transmitter circuit model for measuring the current in each period of the signal and eliminating the resistive effects in the next cycle. In the measurement and correction method disclosed in this patent, current is kept constant only by means of eliminating the downslope in the inductive-resistive coil model, the effects to be created by means of the combination of the capacitive and inductive effects are not taken into consideration. The coil which is mentioned as an inductive ideal component and a resistive parasitic component is such that during the period of measurement by the receiver, a further constant voltage is applied to the whole coil (including parasitic effect) such as zero (0) voltage remains on the ideal coil. There are many systems within the scope of this patent, also there is a feedback and compensation loop and this feedback is not realized from the final magnetic flux of the voltage but is realized by means of creating a feedback loop of the current passing through the coil.

Only eliminating the resistive downslopes by means of measuring the coil current flow is not preventive for the occurrence of other disturbances in the signal. Particularly there will be integral capacitive effects between the wire windings of a coil when it is realized with a plurality of turns and these effects will be influential in the small target conditions where particular fast transitions are expected.

Instead of the measurement made from the coil current, measuring the magnetic field created by the coil by means of a sensor allows for measuring the noise that will occur within the magnetic field particularly during signal transitions. In order to perform real time measurement of the magnetic field, instead of a magnetic sensor, possibly a differential measurement element (for example a receive coil) can be used however in this case the magnetic field measurement resolution will be low during long damped intervals. In this case, the signal is required to be processed since the time derivative of the magnetic field is being measured instead of the magnetic field itself.

In the state of the art, there are patent documents for maintaining the magnetic field of the transmitter constant when required. In the patent document of Allan Westersten No U.S. Pat. No. 7,701,204B2, in the invention of a pulse induction metal detector, besides the compensation solution in terms of increasing and decreasing the transmitter current, it also describes wave forms which points out the importance of holding the transmitter current at a constant level during the measurement made by the receiver however it does not deal with idealization, particularly the parasitic effects after the transition. In this patent, by considering the variability of the reactive component created by ground and coil properties, it is stated that it shall be kept under control by means of feedback, while the feedback is already a method for adapting to change under changing conditions.

In the previous metal detectors of the state of the art, the coil current were being reduced zero by a damping resistor as fast as possible instead of maintaining the pulse current constant. Due to this operating condition, instead of maintaining the coil current constant, keeping it at zero was not a problem. During this reduction, due to self induction, discharge techniques which allow coil voltages that can be high for physically small devices were used. Since this reduction interval is particularly close to the time constants of the small targets, it causes weakness in detecting the small targets and complexity in analyzing thereof within a time interval. In the detectors which are within the present state of the art and registered by Candy or within the patent documents subject to application as the patent of Allan Westersten No U.S. Pat. No. 7,701,204B2, solutions are searched for maintaining the transmitter current constant.

The method of applying a controlled constant voltage to the transmit coil of a metal detector in order to eliminate the damping has taken apart in multiple patents and applications of B. H. Candy. This very basic method is one of the alternatives but excluding “current feedback from transmit coil current” which is one of the essential part of the scope of mentioned patents and applications.

US2008297158 discloses an implementation of a direction finding and magnetic nulling metal detector. Some embodiments of the disclosure provide for a metal detector having multiple resonant circuits and associated coils for transmitting a primary transmit signal, transmitting a magnetic nulling signal, and receiving a receive signal. A controller includes logic to generate transmit signals and to process the received signal in order to determine a gradient vector along one or two dimensions, a depth and whether or not a metal object is ferrous. US2008297158 uses receiving coil for detecting distortions on received signal and it is not suitable for detecting distortions on pulse induction detectors, because in a slow varying magnetic field, like rectangular wave, the electromotive force level is low, and thus providing required sensitivity for correction is very difficult.

EP3339913 discloses a mobile detection device an evaluation of a depth value from the device to an occluded underground elongate utility line. The device comprises at least a first and a second detector unit being arranged with a spacing with respect to one another. There is a compensation unit built to apply an electrical signal to the transmitting loops for establishing a compensation field, which substantially nullifies influences of direct coupling residuals of the excitation field at the detection loops. EP3339913 is not suitable for pulse induction detectors due to above mentioned reason.

US2013207648 discloses a measuring apparatus for detecting a metal object includes two emission coils, a magnetoresistive measuring device, and a control device. The emission coils are configured to produce superimposed magnetic fields. The magnetoresistive measuring device is in the region of both magnetic fields, and is configured to generate an output signal which is dependent on the magnetic field. The control device is configured to supply the emission coils with alternating voltages such that the value of the alternating voltage component of the output signal, which is time synchronized with the alternating voltages, is minimized. The control device is further configured to detect the object when the ratio of the alternating voltages does not correspond to the distances between the magnetoresistive measuring device and the emission coils. US2013207648 uses the magnetoresistive sensor in role of a primary object detection coil.

### SUMMARY

In a metal detector which operates in a time domain within the state of the art; an ideal form of the signal in the time domain of the magnetic field created by the transmitter is an increasing waveform with a constant ramp. It is required for the generated magnetic field to remain constant during the magnetic field measurement of the receiver in order no reactive component but the target signal to occur after completion of that ramp signal.

The accuracy of the transmit signal is also important in metal detectors which operate in the frequency domain but does not transmit a pure sinusoidal magnetic field. In such detectors, this requirement is based on the mode of operation of the receiver part; the preferred embodiment is realized as a metal detector which operates in the time domain.

The invention consists of a closed loop system which enables measurement of the magnetic field created by means of the transmitter and generates a magnetic field by means of at least one auxiliary coil or applies a corrective effect by means of changing the current and voltage of the transmit coil. In a preferred embodiment of the invention, a single turn corrective coil is used. In order to measure the magnetic field to be corrected, a linear sensor with sufficient sensitivity and a response speed must be used. In case a receive coil is used, that receive coil generates a time derivative electromotive force and hence, in a slow varying magnetic field the electromotive force level is low, providing required sensitivity for correction may be difficult. In this case; when magnetic field measurement is made, it is necessary to take the integral of the signal. In the preferred embodiment, in the measurement made for maintaining the magnetic flux constant, a linearly operated magnetoresistive sensor is used. In a multi-turn transmit coil, the damped oscillation effects caused by signal switching of the capacitive and inductive components constitutes a fast noise source. For this reason, the magnetic sensor used should be capable of responding to these fast changes.

A method for creating a corrective magnetic field is to apply a cumulative corrective signal on the coil in addition to the main switching circuit of the transmit coil. This signal can either be a current injection or a constant voltage relevant to the parasitic internal resistance of the transmit coil to maintain the coil current constant. Second method is more preferred in the state of the art because it is simpler than the first one. Another technique is to position one or more windings which will apply corrective magnetic field directly to the current magnetic field that is electrically independent from the main circuit of the transmitter, physically parallel to the main transmitter windings. In this manner with the superposition of the fields, a magnetic field is applied.

The circuit which analyzes the magnetic field and creates the corrective waveform can be in digital or analog structure, the measurement converted to digital and a digitally controlled source within the scope of the present invention is used.

The corrective winding and the measurement sensor are required to have some characteristics (performance, isolation, coil and sensor positioning details) and these are indicated in the detailed description of the invention.

### BRIEF DESCRIPTION OF THE DRAWINGS

FIG. 1: A block diagram of the time domain metal detector comprising magnetic field measurement and compensation by means of a magnetic sensor.

FIG. 2: A block diagram of the time domain metal detector comprising magnetic field and compensation by means of the field measurement coil.

FIG. 3A: In a detector operating in the time domain the graphical illustration of the transmit coil voltage.

FIG. 3B: In a detector operating in the time domain the graphical illustration of the magnetic field which is accepted as ideal.

FIG. 3C: In a detector operating in the time domain the graphical illustration of the magnetic field which comprises parasitic effects.

FIG. 3D: In a detector operating in the time domain the graphical illustration of the magnetic field which is required to be created for eliminating the parasitic effects.

FIG. 3E: In a detector operating in the time domain the graphical illustration of the change of the parasitic magnetic field and corrective magnetic field according to time.

FIG. 4A: A first block diagram of the magnetic field injection over the transmit coil windings.

FIG. 4B: A second block diagram of the magnetic field injection over the transmit coil windings.

FIG. 5: System Control Diagram

### DESCRIPTION OF THE REFERENCE NUMBERS

20—Digital Processing Unit
21—Transmitter Driver Circuit
22—Transmit coil
23—Field measurement coil
24—Magnetic sensor
25—Magnetic receiver input circuit
26—Integrator
27—Analog digital converter (ADC)
28—Digital analog converter (DAC)
29—Current source isolation circuit
30—Controlled current source
31—Field correction coil
32—Receive coil
33—Receiver input circuits
34—Signal preprocessing circuits
35—Analog digital converter (ADC)
36—Controlled constant voltage source
37—Switching component
38—Switching component
101-105: The voltage applied to transmit coil
111-115: Ideal magnetic field required to be created by transmit coil
121-126: The magnetic field created by transmit coil
131-138: Corrective magnetic field
207—System reference
208—Uncompensated transmitter system
209—Ideal transmitter function
210—Sampling system
211—Corrective Coil System
212—Magnetic sensor system

### Detailed Description of the Embodiments

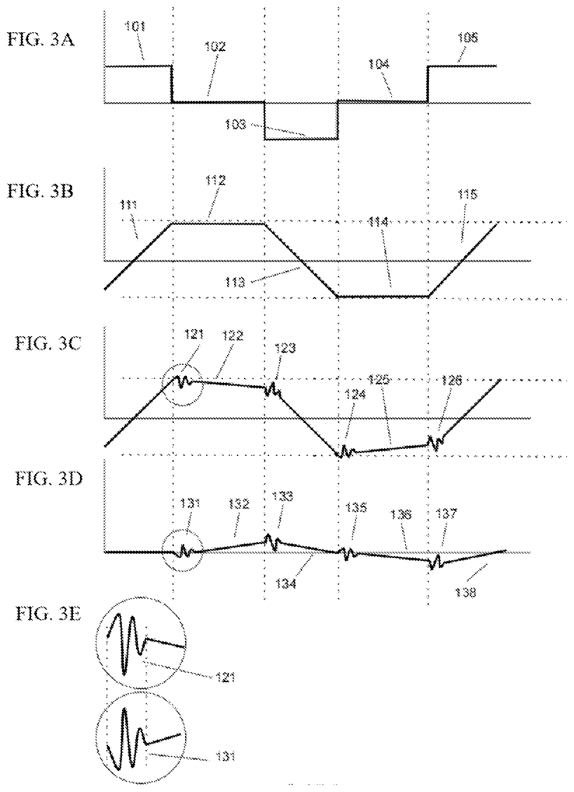

In FIG. 3A, a voltage required to be applied on the coil ends for obtaining the required current through an ideal coil is seen. In case this voltage is applied to an ideal coil, the current flows through this coil and the magnetic field is generated as shown in the graph depicting both waveforms since both are proportional. However the parasitic effects cause the current in a real coil differ from the current of an ideal coil, additionally, cause the generated magnetic field to be differ from the current in a nonlinear manner. Among these parasitic effects, the ones influenced from the capacitive reasons have dynamic characteristic and the disturbances are realized following the transitions in the signal. The effects due to resistive reasons are present whether there is a transition in the signal or not. The presence of both of them exhibits a network behavior, two parasitic effects influence each other, however if change and stability are separated sufficiently, then it may be possible to illustrate and distinguish both effects in the same graph. In this manner one graph in FIG. 3C; is closer to real case which includes parasitic effects of the magnetic field that is created by a real coil. In FIG. 3A when a rectangular wave voltage form referenced as (101) (102) (103) and (104) levels are applied on the ends of an ideal coil, they respectively form the ideal current in FIG. 3B (111), (112), (113) (114), thus the ideal magnetic field, the wave form in FIG. 3B is an integral of the wave form in FIG. 3A with respect to time. In FIG. 3A, wave form indicated as close to the rectangular wave form is in pulse form in real applications (101), (103) with narrow intervals, (102) and (104) wide intervals however due to ease of expression, these four times intervals are shown closer to each other within the scope of FIG. 3A-FIG. 3E.

In FIG. 3C, the parasitic effect which is expressed as non-ideal, close to real signal form (121) shows the disturbed condition of the transition from (111) to (112) as a result of its change over the voltage (102) level in FIG. 3A. The main characteristic of this disturbance which is similar to a damped oscillation is determined by means of the capacitive interaction between the inductive coil windings. This disturbance affects each coil winding current separately and also the magnetic field as a result. The same parasitic effects are the results of the transition respectively from (102) and (103) to (123) and from (103) to (104) as (124) and from (104) to (105) as (126).

In FIG. 3C, the resistive effect is also shown. This effect is the result of voltage level (102) (shown as 0V which also means ends are short-circuit) over a non-ideal coil causing current decrease due to the internal resistance of the non-ideal coil. Although it seems like linear downramp, in case the internal resistance of the coil is stated as a serial resistance, this decrease is mentioned as 0V application over the internal resistance of a coil (R_{Tx}) with inductance (L_{Tx}) is expressed by;

i(t)=i₀e^{t/(L}^{_{Tx}}^{/R}^{_{Tx)}}

This exponential expression within a predetermined time interval is closer to a linear downslope decrease and the decrease which can be seen in (122), can be seen partially independent from the parasitic effect based on the dynamic change in (121).

The waveform which can be able to gain the form in FIG. 3B when it is arithmetically summed with the wave form in FIG. 3A-FIG. 3E is shown in FIG. 3D. It is important that, the form which is referred as (131) in this wave form shall be with totally inverse of the form which is referred as (121). The detail in respect to this section is shown closely in FIG. 3E. Although there is a mutual coupling between the components which will constitute both fields, when this process is realized within a feedback loop, it is possible to express the process as a sum.

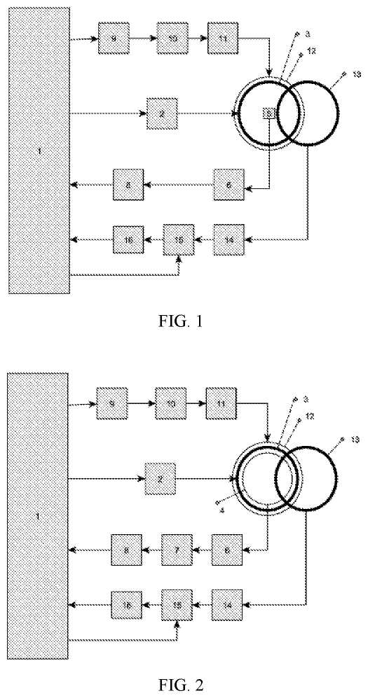

In the preferred embodiment, in a metal detector operating in the time domain, as shown in FIG. 1 and FIG. 2; the signal is received by Receive Coil (13) and processed by the receiver input circuits (14) and signal preprocessing circuits (15) then digitized by means of the analog digital converter (16). These processes are realized in (112) and (114) periods in FIG. 3B. Making measurements in (101) and (103) intervals are also meaningful for a metal detector where the measurement of magnetic characteristics of the target and the environment is required. However in a metal detector wherein the present state of the art is practiced, the effects of the transitions of the magnetic field following (133), (134), (137) and (138) regions and the subsequent regions of the signal in FIG. 3D can be neglected.

The main technique of the invention consists of a compensation using a sub-system by superposition principle which will create minimum distortion in total by means of measuring the distortion seen in FIG. 3C and applying corrective signal by magnetic and/or electronic means seen in FIG. 3D. For this reason the below described system is realized and the system following this description is created by the compensation process within the context of its flow. The preferred embodiment of the invention is the system which is shown in FIG. 1 as a block diagram. The system which is shown in FIG. 2 as a block diagram operates in the same manner however the diagrams are different in respect to realize the measurement by means of using coil or magnetic sensor. When a magnetic field measurement is performed with a coil, according to the Faraday's Law of Induction, the signal generated is time derivative of the magnetic flux according to time, for including the received signal therefrom to the mathematical fact, it is required to take its integral according to time or calculating this signal by considering that it is a derivative. The difference between two measurement methods which will have an effect upon the result is obtaining higher amplitude in fast signal changes of the measurement made by means of the coil, on the other hand lower signal-noise ratio (SNR) in slow changes and thus a decrease in signal measurement accuracy and precision. On the contrary, the fast magnetic sensors which can operate within the magnetic fields created by the detectors are qualified sensors and their costs are higher when compared to the coil costs.

The Digital Signal Processing Unit (1) circuit within FIG. 1 consists of a processor which generates The in the digital signals, maintains analog processes by means of ADC/DAC or equivalent circuit elements, and has a digital signal processing capability. This process is realized by means of electronic elements which are formed by the embedded controllers, digital signal processors (DSP), field programmable gate arrays (FPGA) or by variation and combinations thereof, is integrated, has digital processing ability. For this reason, in conjunction with the other sections of the design, an appropriate Digital Processing Unit (1) can be selected with a processing ability based on the optimization according to cost and purpose. In the preferred embodiment, an FGPA is used which embodies an integrated Processor. This Digital Processing Unit (1) also generates the digital signals which will constitute the reference for the magnetic field of the transmitter of the metal detector. These signals provide high current in the coil by the Transmitter Driver Circuit (2) that consists of various digital switching elements and to recover energy from the magnetic circuit of the Transmit coil (3). In the state of the art, there are many half or full H-Bridge transistor and driver configuration designs not only for the Transmit coil (3) but also for motor drive and similar aims and in the direction of said aim, one of them can be used. The coil driven by this power electronic circuit is a typical with double D (receiver/transmitter) or double receiver D (receiver/transmitter/receiver) or a transmitter winding of the metal detector coil based on induction balance. In the preferred embodiment a receiver/transmit coil with double D structure is used.

In order to measure the magnetic field that is created with this coil, a magnetic sensor (5) is located to the location where the coil generates an optimum field, in preferred embodiment it is located to the planar surface center of the transmit coil (3). In the structure of FIG. 2 which is an alternative form of this system, the field measurement coil (4) which will take the magnetic field generated by the transmit coil (3) as optimum, can be located near to the windings of the transmit coil (3). Here an important aspect is that; regardless of whether using the magnetic sensor (5) or the field measurement coil (4), receiving the field created by the transmit coil (3) in an optimum magnitude to conform the connected electronics. The reason for this, it is provided that the Magnetic sensor (5) or the Field measurement coil (4) is not influenced by the environmental signals which are not generated “directly” by means of the Transmit Coil (3), in other words by the target signals or the signals generated by means of the environmental factors with high permeability and conductivity as little as possible and they are allowed for receiving the linear signal basically by the field generated by the transmitter.

On the other hand, the magnetic field that is created by fast signal changes in the field measurement coil (4) may be more than desired or the magnetic field to which the magnetic sensor (5) is subject, may be above the limits, thus this condition is a variable based on the design. In this case, the location of the field measurement coil (4) or the magnetic sensor (5) can be altered in a manner such that they can be able to sense magnetic field at a lower magnitude. Here, an important aspect is that; it can be disadvantageous to move the field measurement coil (4) or the magnetic sensor (5) away from the planar plane and symmetry of the transmit coil (3). The signal which is converted into potential difference (voltage) by means of the Magnetic Sensor (5) or the Field Measurement Coil (4) is converted to the levels by means of a Magnetic Receiver Input Circuit (6) to which the following stages of electronic circuit can operate. Since the signals received by this circuit are relatively fast (at nanosecond-microsecond level), the characteristics of this circuit are all important. This circuit mainly consists of a band pass filter with amplifier. The output of the Magnetic Receiver Input Circuit (6), is connected directly to the Analog Digital Converter (8) circuit in an embodiment where the Magnetic Sensor (5) is preferred, in case the Field Measurement Coil (4) is used, it will be more appropriate to connect to the Analog Digital Converter (8) through an Analog Integrator (7). Although the mathematical integration process can be realized during digital signal processing period however when we consider the cases where the derivative gives low result for the analog digital converter (8), in order to keep the required accuracy and precision for digitizing, it will be more beneficial to realize this process using analog means. Despite the sampling speed of the Analog Digital Converter (8) is required to be at MS/s range (million samples per second) for an effective result, its resolution can be selected relatively low. Although it is not used in the preferred embodiment, in order to improve the total digital resolution, a plurality of Analog Digital Converter (8) or a multichannel Analog Digital Converter (8) can be used, in mathematical processes the derivative of the signal can be processed together with the signal itself.

The difference between the signal received from the analog digital converter (8) and the referenced signal is the error signal. The error signal is an amplitude that belongs to the magnetic field and the correction signal is required to have the form of the magnetic field. In accordance with the Biot-Savart law, it is known that the magnetic field created due to an electric current is directly proportional with the current. When scaled negative (multiple of −k) is applied, it is possible to obtain the required correction by superposition. In generating the corrective magnetic field, the number of windings is preferred to be less, preferably single, because if the number of windings increase, it will create parasitic effects in the corrective magnetic field as it is in the transmit coil (3). Lower number of windings means to put away the benefit of multiplying the magnetic field based on the number of tours (B α NI). The duration and amplitude of the corrective magnetic field on the ring effect is relatively small within the total duration. For this reason, the current intensity does not constitute a problem. Since the circuit is electrically isolated from the voltage of rest of the system which creates the corrective current and the controlled current source (11), it decreases the capacitive effects and enables flexibility in realizing the current source electronically. For this reason at the source and control inputs of a controlled current source (11), there is a Current Source Isolation Circuit (10). The circuit which controls the current source is a Digital Analog Converter (9) which converts the calculated digital correction information provided by means of the Digital Processing Unit (1) to an analog voltage level. These three sections are required to operate as fast as at least the Analog Digital Converter (8). The Controlled Current Source (11) drives the Field Correction Coil (12). Here the fact that the Field Correction Coil (12) shall not physically apart from the Transmit Coil (3), constituted the same physical shape completely and overlap; otherwise, the magnetic fields generated by two coils may not exhibit regularity in the space around the coil. Arrangement of these two coils totally one in the other is also a situation which is not desired. Although the Current Source Isolation Circuit (10) substantially eliminates the capacitive effects between two systems (one of the aims is this) leaving an optimal distance is beneficial in terms of the stability of two circuits. In this embodiment, it is not possible to use a voltage source for driving the Field Correction Coil (12), in this section it is necessary to use the Controlled Current Source (11). Since these coils share the same magnetic field between the Transmit Coil (3) and the Field Correction Coil (12), there is a mutual induction and the magnetic field created by means of the Transmit Coil (3) causes a magnetic induction on the Field Correction Coil (12), in other words causes a voltage. In order to realize an accurate superposition in the magnetic field, the current of the Field Correction Coil (12) shall be a current which can be controlled independently from this induction.

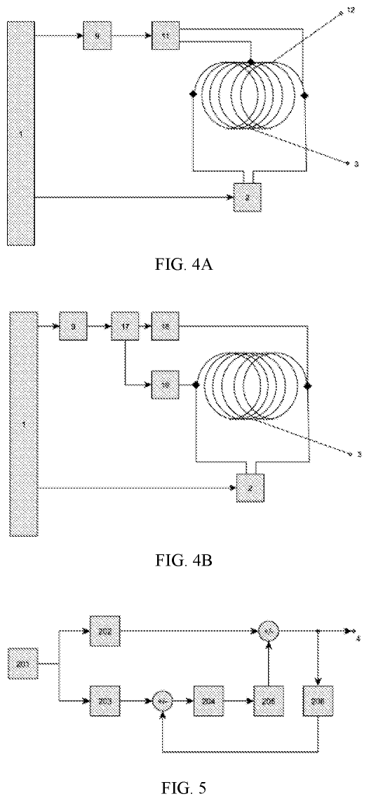

Rather than the Field correction coil (12) is an independent coil, it is possible to use the windings of the transmit coil. In this configuration seen in FIG. 4A, the Field Correction Coil (12) consists of windings which can be at least one turn or at most all turns of the Transmit coil (3). In this case, since one end of each coil system will be common, a full isolation is not possible however this section of the invention can be formed in this manner for particularly resistive parasitic effects and both separate coil and a section of the transmitter can be used. The resistive parasitic effect is an effect which is lasting with longer periods during the period, requires to create more magnetic fields in average although it is a slow effect, for this reason in order to generate averagely more magnetic induction with a lower current, for increasing the N.I multiplication which forms the magnetic field, N (tour numbers) can be increased. In this case, the output of the Controlled Current Source (11) within the scope of the invention is required to be realized in a manner such that it is connected to an internal wire through winding of the Transmit Coil (3) seen in FIG. 4A. This section can be realized by means of a circuit which is isolated by a Current Source Isolation Circuit (10) which is mentioned above, consists of less number of tours in order not to create capacitive interaction. Although constant current source solution is a self-regulating and adaptive option, the current sources are high-impedance sources and it is limiting due to the parasitic characteristics of the switching elements during switching process of the inductive load which consists of a multi-turn coil. As an alternative solution, as can be seen in FIG. 4B, the coil current can provided to be constant by means of switching the generated voltage by a controlled constant voltage source (17) on the transmit coil (3) via the voltage switching components (18) (19). This configuration can be established using simpler components than those in FIG. 4A, but it can be beneficial for controlling the current distortion due to the internal resistance of the Transmit Coil (3). The voltage of the Controlled voltage supply (17) is determined by means of the Digital Analog Converter (9) and the time intervals of this voltage for keeping it constant is applied on the durations in FIG. 3B (112) and (114). This level of voltage is controlled by said magnetic field measurement in order to obtain a constant magnetic field.

The calculation that is realized in the Digital Processing Unit (1) and active compensation process consist of basically the ideal magnetic field formulation, measurement of the generated magnetic field and generating the corrective signal for eliminating the difference between them. The physical system in FIG. 1 is expressed as a process in FIG. 5. The System Reference (201), Ideal Transmitter Function (203), Sampling System (204), calculation process section of the Correction System (205) in FIG. 5 are the processes executed by the Digital Processing Unit (1) in FIG. 1 and FIG. 2. The Uncompensated Transmitter System (202) in FIG. 5 constitutes the process which comprises the Transmit Coil Driver Circuit (2) in FIG. 1 and FIG. 2 and the Transmit Coil (3) which is particularly one of the most important reasons for disturbance, aims correcting its output. The system which is expressed as a Sensor System (206) in FIG. 5 consists of Magnetic Receiver Input Circuit (6), Analog Digital Converter (8) in addition to the Magnetic Sensor (5) in FIG. 1 or the Field Measurement Coil (4) system in FIG. 2. In this system if sensing is made by means of the Field Measurement Coil (4), also the Integrator (7) in FIG. 2 can be used. The Digital Analog Converter (9), the Current Source Isolation Circuit (10), the Controlled Current Source (11) and the Field Correction Coil (12) in FIG. 1 and FIG. 2 constitute the process at the output of the Correction System (205) in FIG. 5.

As it can be seen in the system control diagram of FIG. 5, the voltage pulses form the System Reference (201). This reference is same with the voltage signal form seen in FIG. 3A. The integral of this signal form within time domain seen in FIG. 3B, is the magnetic field required to be generated by the Transmit Coil (3) when the parasitic effects are excluded. The Ideal Transmitter Function (203) seen in FIG. 5 provides analytic equivalent of this field and in the Laplace domain with system parameters, this function can be expressed as follows; M(s)=k/s [1] Here the k value is a scaling value, and is a value which can be calculated according to the measurement results by the Digital Processing Unit (1) in the FIG. 1 and FIG. 2. “1/s” in [1] statement is the equivalent of the Laplace transform of the integral process in time domain. In the time field, the integral of the rectangular wave form of (101), (102), (103) and (104) in FIG. 3A-FIG. 3E is the wave form of (111), (112), (113) and (114) in the same figure. This wave form is an “ideal model”, its uncorrected situation is formed by means of the Transmitter Driver Circuit (2) and the Transmit Coil (3) in FIG. 1 and FIG. 2, at the same time the form of the magnetic field to be created by means of the Uncorrected Transmitter System (202) in FIG. 5 will be similar to the wave form in FIG. 3A-FIG. 3E. The difference between the Magnetic Sensor System (206) output which measures the transmitter magnetic field in FIG. 5 and the Ideal Transmitter Function (203) will give the signal between the desired and the generated, namely the “error signal”. The sampling system (204) is a system where the record of the error signal occurred along at least one signal period within the time domain and the compensation is realized after it is added to the output of the uncompensated transmitter system (202) by means of the Correction System (205). The easiest method for correction is to add the records to the present time domain records in the sampling system (204) after summing; however in order to improve the system stability in the long term, a digital filter can be devised to the sampling system (204). In the preferred embodiment, the sampling system (204) logs to record in the time domain and after digital filtering, it updates these records. However this illustration system (204) is not required to operate in the time domain, instead of this, this function can be defined in an analytically by means of analytical function modeling methods. In any case, this correction function is required to operate in a synchronous manner with the ideal transmitter function (203) and at the same time it is cyclic. In such a system, if the uncompensated transmitter system (202) is designed as time invariant, establishing the sampling system (204) with the System Identification (SI) only when the device is initially operated or with determined reasonable intervals or whenever the user requires. The magnetic field which is required to be added for correction is as it is in FIG. 3D.

As an alternative, it is possible to obtain the same functionality of the Controlled Constant Voltage Source (17) by using a constant voltage source fixed to an optimum voltage and setting a current to a level that will be constant in intervals (112) and (114) only by varying the time interval of (111) and (113) in FIG. 3B. In this method, the constant current is obtained by using the coil current as the parameter in the relation between the coil current, a constant voltage and the parasitic resistance. This parameter can be controlled by the Digital Processing Unit (1) by setting the pulse width since the targeted current is a function of the ramp interval and the inductance (the slope of ramp).

The compensation process is realized as a digital active system in the preferred embodiment however as different circuits which will create and analog or digital context, also it is possible to establish a compensation system which will make adjustment in the signal by means of the digitally supported or unique analog principles. In any of the cases, the following main processes will be applied directly or indirectly as a closed loop or in a predetermined order.

D) Converting the instant value or the time derivative of the magnetic field to an electrical signal

E) Determination of the error by comparing the generated magnetic field to the ideal function

F) Adding the corrective signal to the magnetic field directly or indirectly by means of at least one electronic and/or electronic/magnetic system.

In the preferred embodiment, the corrective signal is added to the magnetic field using a separate coil however it is possible to realize the signal, particularly the signal within the resistive region by means of analog and digital processes by injecting current to the transmit coil and by making addition on the coil voltage by this method. Since the correction of the capacitive effects by means of a method except creating a magnetic field is not an easy process, the correction process can be realized alternatively as a system which can be able to eliminate the resistive effects by current or voltage superposition on at least one winding of the transmit coil (3), the capacitive effects by means of injecting to the partial windings of the transmit coil (3). Here it is possible to correct the capacitive effects with a system which is fast however does not require considerable energy in total. Regardless of how the transmitter injection is made for this correction, in order to eliminate the system from the internal capacitive parasitic effects, it is required to be realized with the possible lowest number of windings. In correcting the resistive effects, magnetic field and/or current injection will be take part for relatively a long interval correction. For this reason in order to realize this correction with single or less number of tours, a high average current will be required, thus for obtaining the required magnetic flux, the number of tours shall be higher to have the required (N.I) (current.tour) value. Thus, in this case the relevant coil of the transmitter or an independent coil are required to have a plurality of tours. In order to eliminate both parasitic effects, it is possible to use both methods in conjunction.

What is claimed is:

1- A metal detector, comprising:
a transmit coil driven with a rectangular wave pulse signal,
a receive coil,
at least one sensor configured to detect a magnetic field created by the transmit coil,
an error detection system configured to determine a distortion by comparing a detected magnetic field to an ideal function, and
a corrective system configured to eliminate the distortion by an additional magnetic field created according to a detected distortion and/or by altering a current by a voltage applied to the transmit coil,
wherein the at least one sensor comprises a magnetoresistive sensor.

2- The metal detector according to claim 1, wherein the at least one sensor comprises at least one field measurement coil and/or at least one sensor having a magnetic field sensing feature.

3. The metal detector according to claim 2, wherein the at least one sensor comprises a hall effect sensor and/or a magnetic flux gate sensor and/or a micro electromechanical sensor (MEMS) and/or a Lorentz Force based sensor and/or a piezoresistive sensor and/or a magnetic sensor operating with optical sensing and/or a resonator based a magnetic sensor and/or an eddy current based a magnetic sensor.

4-(canceled)

5-(canceled)

6- The metal detector according to claim 2, further comprising at least one magnetic receiver input circuit configured to convert a magnetic field signal detected as a potential difference (voltage) by the at least one sensor and/or the at least one field measurement coil to subsequent electronic circuits at appropriate levels.

7- The metal detector according to claim 1, further comprising at least one analog digital converter and/or multi channeled analog digital converter enabling a conversion in order to compare received signal to a ideal sample.

8-(Currently Amended) The metal detector according to claim 2, further comprising at least one integrator is positioned between magnetic receiver input circuit and an analog digital converter when the at least one field measurement coil is used.

9- The metal detector according to claim 1, further comprising at least one controlled current source configured to create a corrective signal generated by using active and/or passive elements.

10- The metal detector according to claim 9, further comprising a current source isolation circuit enabling the at least one controlled current source to be isolated electrically from a system voltage and isolating supply and control inputs and/or output of the at least one controlled current source from the system voltage.

11- The metal detector according to claim 9, further comprising at least one field correction coil configured to apply the corrective signal generated in the at least one controlled current source on the magnetic field created by the transmit coil.

12- The metal detector according to claim 1, further comprising at least one controlled constant voltage source constituted by active or passive components, in order to generate a corrective signal.

13- The metal detector according to claim 17, further comprising at least one switching component to apply a voltage generate by a controlled constant voltage source (17) onto the transmit coil.

14- The metal detector according to claim 17, wherein a current of the transmit coil (3) is maintained using a constant voltage switched to the transmit coil and a level of the current is controlled using a ramping time interval.

15- The metal detector according to claim 1, further comprising a field correction coil positioned as an independent coil and/or included within at least one winding of the transmit coil.

16- A method for enabling sensing of a distortion in a magnetic field created by a transmit coil in a metal detector and a correction of a sensed distortion in the magnetic field, consisting of the following process steps;
converting an instant value or a time derivative of the magnetic field generated by the transmit coil to an electrical signal;
determination of an error signal by comparing the magnetic field generated to an ideal function;
generating a corrective signal by using the error signal;
adding the corrective signal to the magnetic field created by the transmit coil directly or indirectly using at least one electronic and/or electronic/magnetic system.

17- The metal detector according to claim 1, further comprising a field correction coil consisting of at least one turn of the transmit coil, wherein an output of a controlled current source is configured to be connected to an internal wire through winding of the transmit coil.

18- The metal detector according to claim 6, further comprising at least one integrator positioned between the at least one magnetic receiver input circuit and an analog digital converter when the at least one field measurement coil is used.

19- The metal detector according to claim 7, further comprising at least one integrator positioned between a magnetic receiver input circuit and the at least one analog digital converter when the at least one field measurement coil is used.

20- The metal detector according to claim 10, further comprising at least one field correction coil configured to apply the corrective signal generated in the at least one controlled current source on the magnetic field created by the transmit coil.
